(19) United States
(12) Patent Application Publication
(10) Pub. No.: US 2012/0167970 A1
(43) Pub. Date: Jul. 5, 2012

(54) METHOD FOR PRODUCING A LIGHT TRAPPING LAYER ON A TRANSPARENT SUBSTRATE FOR USE IN A PHOTOVOLTAIC DEVICE, A METHOD FOR PRODUCING A PHOTOVOLTAIC DEVICE AS WELL AS SUCH A PHOTOVOLTAIC DEVICE

(76) Inventors: Hermanus Johannes Borg, New Dehli (IN); Patrick Godefridus Jacobus Maria Peeters, New Delhi (IN)

(21) Appl. No.: 13/061,949

(22) Filed: Mar. 2, 2011

(30) Foreign Application Priority Data
Sep. 3, 2008 (NL) NL 1035889
Sep. 3, 2009 (NL) PCT/NL2009/000169

(51) Int. Cl. H01L 31/0232; H01L 31/18; H01L 31/0236

(52) U.S. Cl. 136/256; 438/71; 257/E31.13

(57) ABSTRACT

A method to manufacture a thin film photovoltaic device is provided. The method involves mastering of sub-micron features onto a first master substrate, followed by duplication of the master surface onto one or multiple stampers, and replication of the micro-texture into the superstrate or substrate surface by using the multiple stampers. The method also discloses depositing a TCO layer on the superstrate or substrate surface having the sub-micron features, such that a side of the TCO layer distant from the superstrate or substrate surface having the sub-micron features. Thereafter, the method includes depositing the one or more semiconductor layers, the back contact layer and the cover substrate.

### FIELD OF INVENTION

The invention disclosed herein relates, in general, to thin film photovoltaic devices. More specifically, the present invention relates to a method for producing a light trapping layer on substrates for use in the thin film photovoltaic devices.

### BACKGROUND

In functioning of semiconductor devices like thin film solar cells, light management is a very critical aspect that substantially affects the efficiency of such devices. Therefore, the efficiency of a thin-film solar cell/module is significantly determined by its ability to capture the maximum amount of incident solar light and convert this into electrical energy. To maximize the amount of light absorbed in the absorber layer of the solar cell, substrates or superstrates with a random micro-texture are used to scatter the incident light, in order to increase the optical path length of the light in the absorber layer, and hence absorb as much light as possible.

Current methods to produce such random micro-texture in solar cell superstrate configurations include:

(1) an atmospheric pressure chemical vapor deposition process of a TCO front contact layer,

(2) a wet-chemical etching process of a sputter-deposited TCO (transparent conducting oxide) front contact layer, and

(3) LPCVD (low-pressure chemical vapor deposition) of the TCO front contact layer.

In solar cells, substrate configurations with a micro-textured back contact layer are often used, produced by wet-chemical etching of the metal contact layer. One of the drawback of these methods is that the micro-texture is random in nature and the micro-texture parameters cannot be changed easily and independently, as they are dependent on the type of materials used and the process parameters. Further, current production processes are such that it is not possible to independently optimize the micro-texture parameters for maximum light-trapping in a given solar cell layer stack design.

It is known that solar cells deposited on superstrates with an optimized periodic sub-micron structure can have significantly higher power conversion efficiency than current solar cells deposited on superstrates with a random micro-texture. Although the simulation results are promising, a practical proof of the same has not been reported yet and such theoretical optimal structures have not been made yet.

In light of the above discussion, there is a need for an improved method to produce a well-defined (periodic) micro-texture onto substrates or superstrates for thin-film solar cells, in order to maximize the light-trapping efficiency of thin-film solar cells.

### SUMMARY

The invention relates to method for producing a light trapping layer on a transparent superstrate for use in a photovoltaic device comprising at least the steps of:
i) providing a transparent superstrate having a substantially flat surface;
ii) applying a light trapping texture on the surface of the transparent superstrate;
iii) applying a TCO layer on the surface, the TCO layer also including a light trapping texture on a surface distant from the surface.

The invention also relates to method for producing a photovoltaic, device comprising at least the steps of:
i) providing a transparent superstrate having a substantially flat surface;
ii) applying a light trapping texture on the surface of the transparent superstrate;
iii) applying a TCO layer on the surface, the TCO layer also including a light trapping texture on a surface distant from the surface;
iv) depositing one or more semiconductor layers for photoelectric conversion on the light trapping texture;
v) depositing a back contact layer on the one or more semiconductor layers; and
iv) providing a cover substrate on the one or more semiconductor layers.

The invention moreover relates to a photovoltaic device for photoelectric conversion of incident solar light comprising a stack of at least: a transparent superstrate having a substantially flat surface; a textured light trapping layer on the surface; a TCO layer on the surface, wherein the TCO layer also including a light trapping texture on a surface distant from the surface; one or more semiconductor layers for photoelectric conversion deposited on the TCO layer; a back cover substrate and a cover substrate.

The present invention provides a new method to produce a well-defined (periodic) micro-texture onto substrates or superstrates for thin-film solar cells, in order to maximize the light-trapping efficiency of thin-film solar cells. The method includes the formation of the sub-micron sized features onto a stamper, as well as the replication of this micro-texture onto large area solar cell substrates and superstrates.

The method according to the invention is developed to produce a thin film photovoltaic device having well-defined periodic micro-texture onto a solar glass superstrate or substrate. The method involves mastering of sub-micron features onto a first master substrate, followed by duplication of the master surface onto one or multiple stampers, and replication of the micro-texture into the superstrate or substrate surface by using the multiple stampers. The method also discloses depositing a TCO layer on the superstrate or substrate surface having the sub-micron features, such that a side of the TCO layer distant from the superstrate or substrate surface having the sub-micron features. Thereafter, the method includes depositing the one or more semiconductor layers, the back contact layer and the cover substrate.

The invention describes a method to produce a defined (periodic) micro-texture onto a solar cell substrate or superstrate to improve light-trapping in the solar cell. The method proposed can produce a well-defined periodic micro-texture with sub-micrometer dimensions, resulting in diffraction of the incident light and leading to increased absorption of light in the solar cell. With the proposed method the parameters of the micro-texture can be varied and optimized in an independent way. The proposed method can be applied both in substrate or superstrate configuration and on large areas in a cost-effective and reproducible way.

### BRIEF DESCRIPTION OF FIGURES

The features of the present invention, which are believed to be novel, are set forth with particularity in the appended claims. The invention may best be understood by reference to the following description, taken in conjunction with the accompanying drawings. These drawings and the associated description are provided to illustrate some embodiments of the invention, and not to limit the scope of the invention.

FIG. 1 shows a superstrate (FIG. 1a) and a substrate configuration (FIG. 1b) for thin-film solar cells according to the state of the art. In the superstrate configuration (FIG. 1a), a glass plate with micro-textured TCO layer is used as start point, and the solar cell layer stack is deposited in the sequence p-doped semiconductor, i-doped semiconductor, n-doped semiconductor, followed by the back contact, here composed by a TCO and metal layer and an interlayer deposited on a glass back plate.

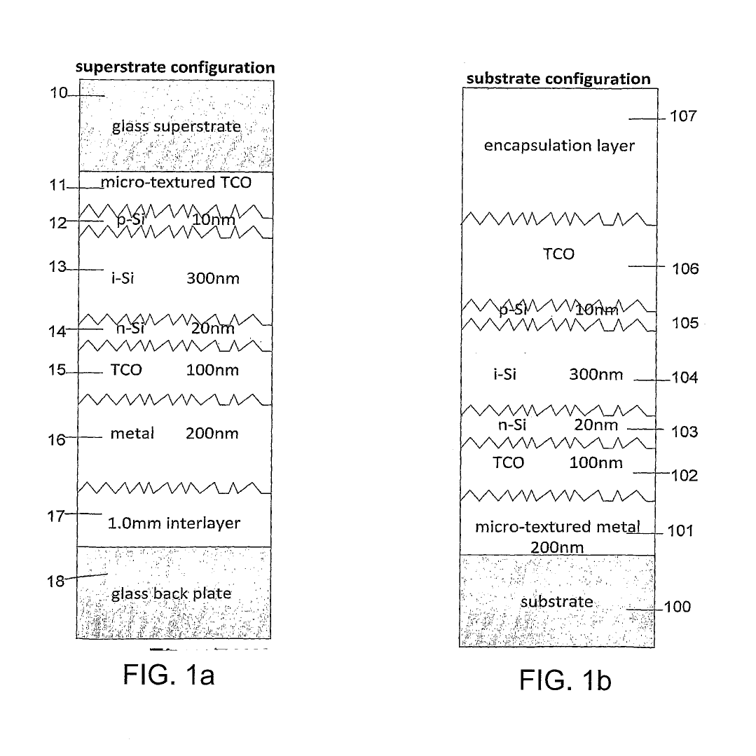

In the substrate configuration (FIG. 1b), a substrate with micro-textured back contact layer (101-102) is used as starting point, and the solar cell layer stack is deposited in the sequence n-doped semiconductor, i-doped semiconductor, p-doped semiconductor, followed by the front contact (here TCO). In both types of structure additional layers are present to protect the structure against adverse effects of the environment.

FIG. 2 shows schematically a mastering process in accordance with an embodiment of the invention. A photoresist layer 21 is applied onto a glass master substrate 20 (FIG. 2a). By using a scanning focused laser spot the photoresist layer is locally illuminated (reference numerals 22 in FIG. 2b). By using a suitable developer the illuminated photo-resist material 21 is dissolved, leaving a defined sub-micron texture 23 (FIG. 2c). A nickel metal contact layer 24 is deposited onto the developed glass master substrate 20-21 as a seed layer for the electro-plating process.

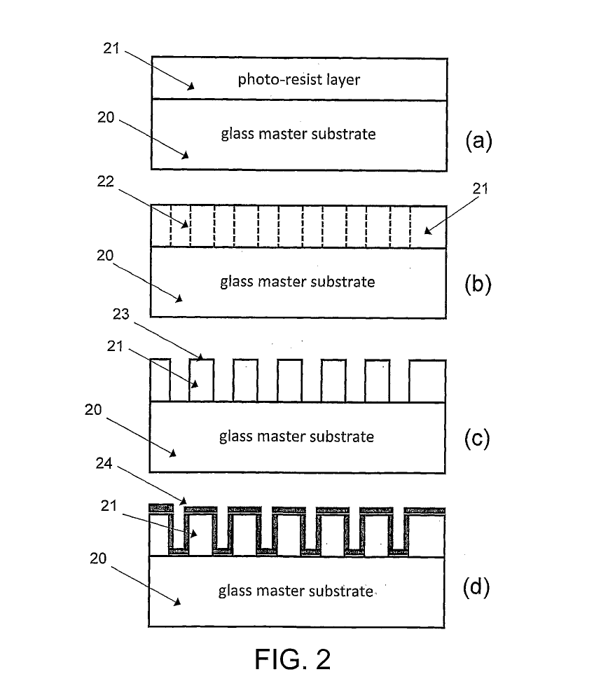

FIG. 3 shows schematically the electro-plating process, in accordance with an embodiment of the invention. Starting point is the developed glass master plate 20-21 with the nickel metal contact layer 24, which is used as electrode in the electro-plating process (FIG. 3a). Subsequently a nickel father stamper 30 with a thickness of typically a few hundred micrometer is grown by electro-plating on the developed glass master plate 20-21 with the nickel metal contact layer 24 (FIG. 3b). The father stamper 30 is subsequently separated from the glass master 20-21, resulting in a negative image 31 of the mastered sub-micron texture 23.

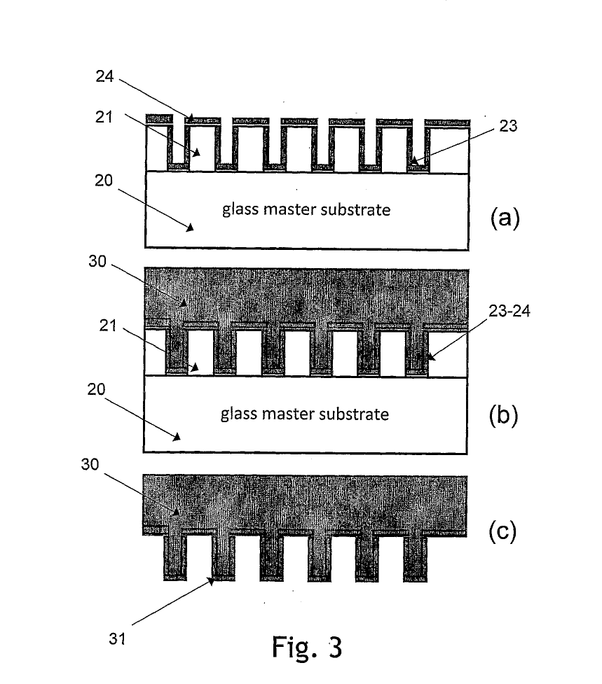

FIG. 4 shows schematically the family process in electro-plating, in accordance with an embodiment of the invention. Starting point is the nickel father stamper 30 with the negative image 31 of the mastered sub-micron texture 23 (FIG. 4a). A thin passivation layer 40 is formed on the textured surface 31 by oxidizing the nickel material of the father stamper 30, either via an electrochemical or plasma process (FIG. 4b). Subsequently a nickel mother stamper 41 is grown by electro-plating (FIG. 4c). As a last step the mother stamper 41 is separated from the father stamper 30 at the passivation layer 40. The resulting mother stamper 41 bears a positive image of the mastered sub-micron texture 23 (FIG. 4d).

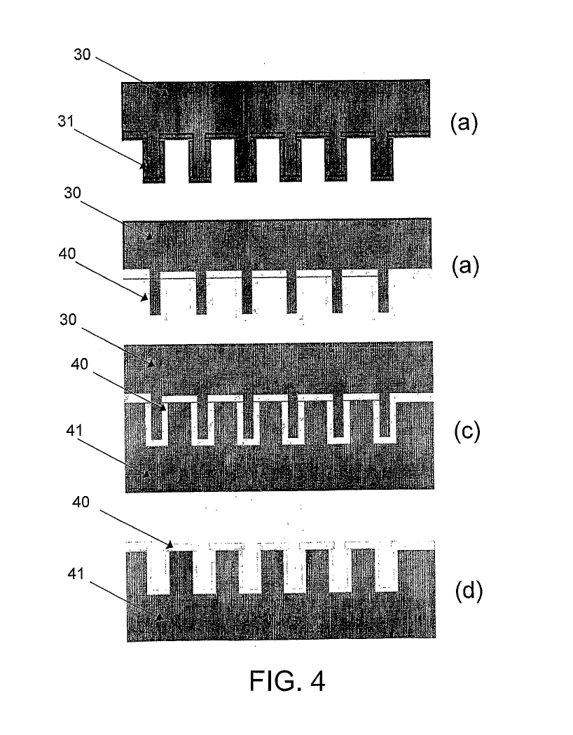

FIG. 5 shows schematically the replication process of the sub-micron texture onto the solar cell superstrate, in accordance with an embodiment of the invention. A liquid replication layer 50 with a thickness of a few tens of microns is applied onto the superstrate 51 (FIG. 5a). Then the stamper 30 is pressed into the replication 50 layer with a certain force. The replication layer 50 is cured, e.g. by using UV irradiation or applying heat (reference numeral 52 in FIG. 5b), and the sub-micron texture 23 is fixed into the replication layer 50. Subsequently, the stamper 30 is separated and a superstrate 51 with the sub-micron texture is left (FIG. 5c).

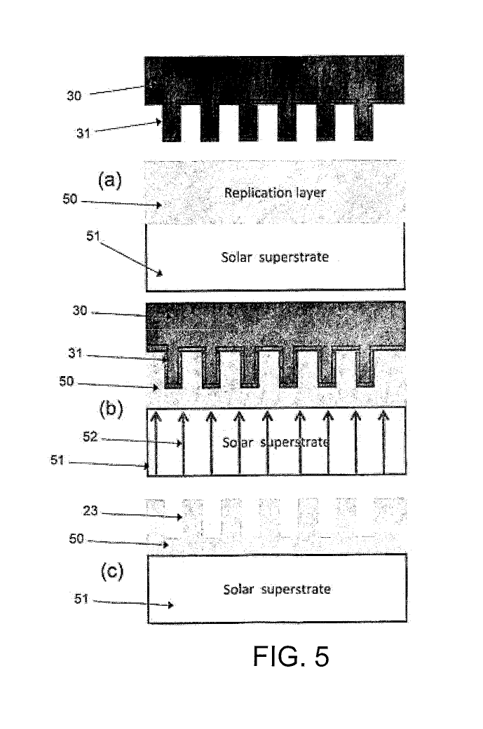

FIG. 6a another example of the state of the art and FIGS. 6b-6d are other embodiments of the invention.

FIGS. 7a and 7b are other examples of embodiments of the invention.

FIG. 8 illustrates a flow chart describing an exemplary method of manufacturing a thin film photovoltaic device, in accordance with an embodiment of the present invention.

Those with ordinary skill in the art will appreciate that the elements in the figures are illustrated for simplicity and clarity and are not necessarily drawn to scale. For example, the dimensions of some of the elements in the figures may be exaggerated, relative to other elements, in order to improve the understanding of the present invention.

There may be additional structures described in the foregoing application that are not depicted on one of the described drawings. In the event such a structure is described, but not depicted in a drawing, the absence of such a drawing should not be considered as an omission of such design from the specification.

### DETAILED DESCRIPTION OF THE INVENTION

Before describing the present invention in detail, it should be observed that the present invention utilizes a combination of method steps and apparatus components related to a method of manufacturing a semiconductor device. Accordingly the apparatus components and the method steps have been represented where appropriate by conventional symbols in the drawings, showing only specific details that are pertinent for an understanding of the present invention so as not to obscure the disclosure with details that will be readily apparent to those with ordinary skill in the art having the benefit of the description herein.

While the specification concludes with the claims defining the features of the invention that are regarded as novel, it is believed that the invention will be better understood from a consideration of the following description in conjunction with the drawings, in which like reference numerals are carried forward.

As required, detailed embodiments of the present invention are disclosed herein; however, it is to be understood that the disclosed embodiments are merely exemplary of the invention, which can be embodied in various forms. Therefore, specific structural and functional details disclosed herein are not to be interpreted as limiting, but merely as a basis for the claims and as a representative basis for teaching one skilled in the art to variously employ the present invention in virtually any appropriately detailed structure. Further, the tennis and phrases used herein are not intended to be limiting but rather to provide an understandable description of the invention.

The terms “a” or “an”, as used herein, are defined as one or more than one. The term “another”, as used herein, is defined as at least a second or more. The terms “including” and/or “having” as used herein, are defined as comprising (i.e. open transition). The term “coupled” or “operatively coupled” as used herein, is defined as connected, although not necessarily directly, and not necessarily mechanically.

The method according to the invention to produce a well-defined periodic micro-texture onto a solar glass superstrate or substrate involves a number of major steps, i.e. (1) mastering of the sub-micron features 23 onto a first master substrate 20, (2) duplication of the master surface 20 into one or multiple stampers 30, and (3) replication of the micro-texture 23 into the superstrate 10 or substrate surface 100 by using the stampers 30. The inventive method disclosed will address all three process steps, but focuses mainly on steps 1 and 3.

Mastering Process

The sub-micron sized (periodic) micro-texture is first produced onto a master substrate with a photo-resist layer. by using a photo-lithographic process or thermo-lithographic (PTM) process. The master substrate can be a glass plate, a semiconductor wafer or a flat metal plate, but is not necessarily be restricted to that. The photo-resist layer is typically a novolac, but is not necessarily restricted to that and may include phase-transition materials).

During the mastering process the photo-resist layer is locally illuminated by using a focused sub-micron-sized laser spot. The laser spot can be scanned over the photo-resist layer, either by moving the substrate under a stationary spot, or by moving the spot over a stationary substrate, or by a combination of both. One well-known method is to use a rotating master plate in combination with a linearly moving laser spot in the radial direction to form spiral-shaped tracks with features. Another method is to use an x,y-stage to move either the master plate or the laser spot in the lateral direction.

The light intensity of the laser spot can be modulated, so that the illumination level of the photo-resist can be varied as a function of time and/or position. In this way a variety of feature shapes can be realized. For example, continuous intensity of the laser spot combined with a constant linear movement will result in line-shaped features, whereas a pulse-modulated (intensity on-off) laser spot will result in dot- or dash-shaped features.

The depth of the micro-texture features can be controlled by the thickness of the photo-resist layer as well as the illumination level during light exposure. The lateral size of the features is determined by a variety of parameters, i.e. the wavelength I of the laser, the numerical aperture NA of the objective lens, the intensity level of the light, the duration of the pulse and the relative speed between laser spot and master substrate.

Typically, the minimal features that can be mastered with the focused laser spot have dimensions on the order of λ/(2.NA). Using laser light in the visible or deep-UV range of the light spectrum and by using an objective lens with an NA in the range from 0.5 to 0.9 the resulting minimal feature size will typically be in the order of 100-800 nm.

After local illumination the photo-resist layer is processed (the so-called development process), in general by exposing it to a diluted acid or base solution. Depending on the type of photo-resist and etchant used, the illuminated part of the photo-resist will exhibit either a higher or lower etching rate than its non-illuminated counterpart, resulting in the formation of the (defined) micro-texture in the surface of the remaining photo-resist layer.

The details of the micro-texture are not only determined by the illumination process, as described above, but can also be manipulated by the process parameters of the development process, such as type of etchant, concentration of the etchant and development time.

Duplication of the Master

After development, the master substrate with the micro-textured photo-resist layer is being duplicated to form a series of stampers that can be used for the large area replication process of the micro-texture onto solar superstrates or substrates. A possible way to duplicate the master is by using an electroplating process, but other methods are possible as well. In the electro-plating process the developed master plate is first sputtered with a metal layer, typically a nickel-alloy or a silver-alloy, to form a conducting electrode and a seed layer for the plating process.

Subsequently a relatively thick (typically few hundred micron) metal stamper, typically nickel, is grown on top of this seed layer. The stamper is subsequently removed from the master substrate, and contains a negative image of the master's micro-texture at its surface. The so-produced first stamper (also called the father stamper) can be used for the replication of the micro-texture onto superstrates or substrates. Alternatively, it can also be used to duplicate the micro-texture into a family of multiple stampers.

In this latter process first a very thin separation layer (typically a monolayer) is formed at the surface of the stamper, and subsequently another stamper is grown by electroplating. The newly grown stamper can be removed from the first stamper, and bears a positive image of the original master's micro-texture at its surface. The duplication process of the first stamper can be repeated several times, resulting in a family of duplicate stampers with a positive image of the master's micro-texture. In the same way, one of the stampers with the positive image of the master's micro-texture can be used to form a family of duplicate stampers with a negative image of the master's micro-texture.

Further, the method of manufacturing the stamper described above is such that it makes independent optimization of the micro-texture for maximum light-trapping possible.

Replication of the Micro-Texture

The stampers formed by the above described duplication process can be used to replicate the micro-texture onto the solar cell substrate or superstrate. Several methods can be used for such replication process. A well-known method is to apply a thin layer of a viscous UV-curable material, such as a photo-polymer lacquer or a sol-gel material, onto the superstrate or substrate, to press the stamper with the micro-textured surface into this layer, and to apply a UV-curing process to freeze the micro-texture into the surface of the replication material.

Another known method is to apply a thin layer of a viscous thermally curable material, such as a photo-polymer lacquer or a sol-gel material, onto the superstrate or substrate, to press the stamper with the micro-textured surface into this layer, and to apply heat to freeze the micro-texture into the surface of the replication material.

Another method to replicate the micro-texture into the superstrate or substrate is by pressing the stamper into the superstrate or substrate while it is being heated above its deformation (glass transition) temperature (hot-embossing), followed by a rapid cooling process. Yet another method of replication is by injection molding, in which the stamper is mounted into the injection molding cavity and the micro-texture is formed at the surface of the superstrate or substrate.

One of the benefits of the described mastering method to produce micro-texture at the superstrate or substrate surface is that the dimensions of the sub-micron sized features can be precisely optimized and controlled. The lateral dimensions and depth of the features can be optimized independently. The mastering method is ideally suited to produce periodic or quasi-periodic structures with a controlled and precise distance at sub-micron level between consecutive patterns. Such micro-textures can be optimized to form an anti-reflective layer, a diffractive grating or a combination of both. Also, additional randomization is possible by either modulation of the light intensity or of the spot position.

The electro-plating duplication process to make multiple duplicate stampers from a single master is very accurate even at dimensions on sub-micron size scale and allows easy and inexpensive scale up to large area surfaces.

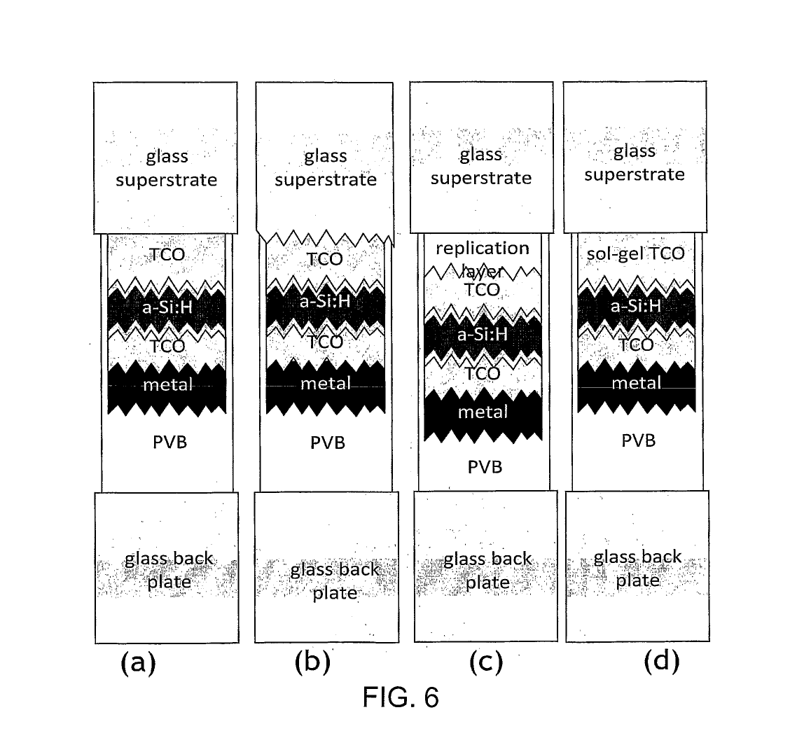

FIG. 6a shows the superstrate and substrate configuration for thin-film solar cells according to the state of the art, wherein the texture at the TCO surface is formed either during deposition process (such as APCVD, LPCVD) or by wet-etching of a uniform TCO layer.

In FIG. 6b another embodiment according to the invention is shown, wherein a (periodic) (micro-)texture is applied at the surface of a glass substrate, using the methods as described in the above description. The TCO layer (with or without a micro-texture) is subsequently deposited using conventional known methods on top of this (periodically) (micro-)textured glass substrate and subsequently, the semiconductor layers and back contact layers are deposited.

In FIG. 6c yet another embodiment according to the invention is shown, wherein a (periodic) (micro-)texture is applied at the surface of a replication layer on a glass substrate, using the methods as described in the above description.

The TCO layer (with or without a micro-texture) is subsequently deposited with conventional known methods on top of this (periodically) (micro-)textured replication layer on the glass substrate and subsequently, the semiconductor layers and back contact layers are deposited.

In FIG. 6d yet another embodiment according to the invention is shown, wherein a (periodic) (micro-)texture is applied at the surface of a transparent conductive sol-gel layer, using methods as described in this description and subsequently, the semiconductor layers and back contact layers are deposited.

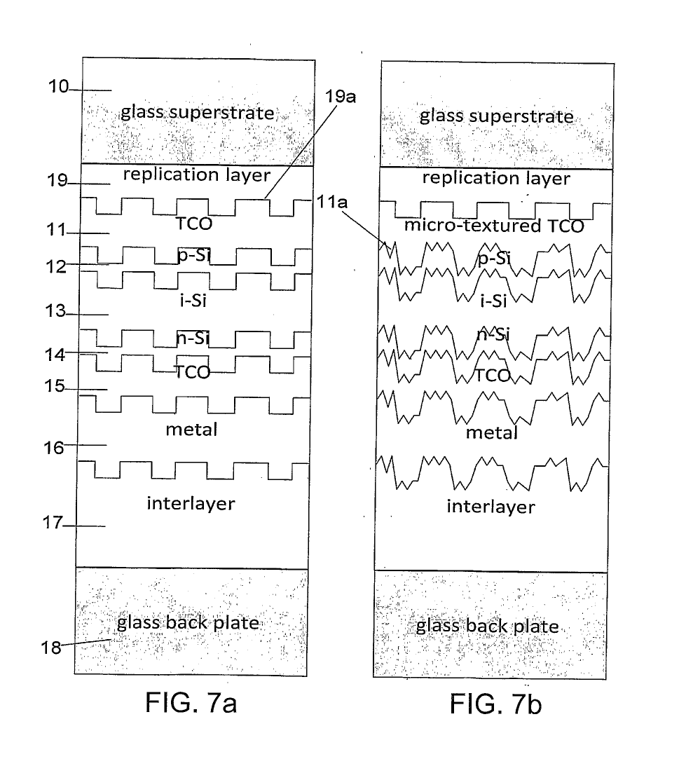

As a further specific embodiment in FIGS. 7a and 7b it is suggested to provide a TCO layer being textured according to the invention with an additional micro-texture applied to the texture already present. In FIG. 7a the replication layer 19 exhibits a texture 19a having a periodic, low frequency shape or configuration, which periodic texture is also present in the TCO layer 11 and semiconductor layers 12-16 being deposited on the replication and TCO layer 19-11.

In FIG. 7b the replication layer 19 also exhibits a texture 19a having a periodic, low frequency shape or configuration. However the TCO layer 11 being deposited on the replication layer is provided with an additional micro-texture 11a having a random, low frequency shape or configuration. Likewise, said additional micro-texture is also present in the semiconductor layers 12-16 being deposited on the replication and TCO layer 19-11.

This micro-structure can be applied by adjusting the process parameters of the deposition-process, for example by means of a wet or dry etching step.

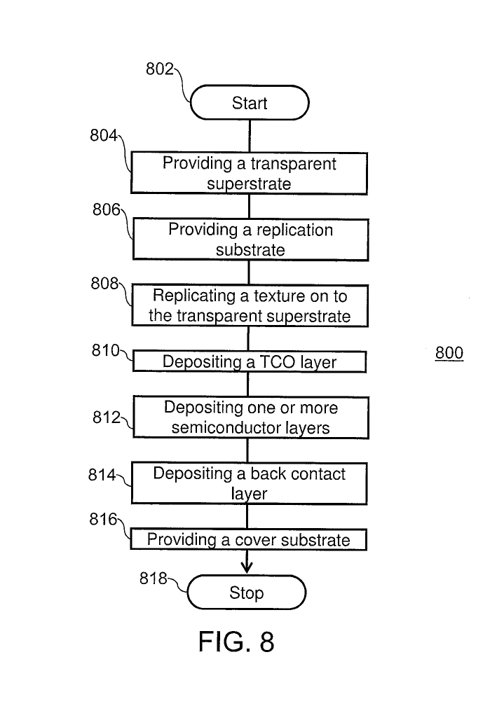

Moving on to FIG. 8, there is shown a flowchart depicting a method 800 of manufacturing a thin film photovoltaic device in accordance with an embodiment of the present invention. At step 802, a transparent superstrate, for example, transparent superstrate 10, having a substantially flat surface is provided.

Thereafter, at step 804 a replication substrate is provided. The replication substrate can be a stamper like the one described above. The stamper includes a negative image of a micro-texture at its surface. The stamper containing the micro-texture can be used for replicating the micro-texture onto the superstrate at step 806. The superstrate 10 is provided with the micro-texture, for example a light trapping texture 19a, on a surface.

Several methods can be used for replicating the light trapping texture from the stamper to the superstrate 10. For example, in real life applications, a thin layer of a viscous UV-curable material, such as a photo-polymer lacquer or a sol-gel material can be applied onto the superstrate 10. Thereafter, the stamper with the micro-texture can be pressed into the thin layer, followed by application of a UV-curing process to freeze the micro-texture into the surface of the superstrate 10.

Another example of this could be to apply a thin layer of a viscous thermally curable material, such as a photo-polymer lacquer or a sol-gel material, onto the superstrate 10. Thereafter, the stamper with the micro-texture can be pressed into the thin layer, followed by application of heat to freeze the micro-texture into the surface of the superstrate 10.

Another method to replicate the micro-texture into the superstrate 10 is by pressing the stamper into the superstrate 10 while it is being heated above its deformation (glass transition) temperature (hot-embossing), followed by a rapid cooling process. Yet another method of replication is by injection molding, in which the stamper is mounted into an injection molding cavity and the micro-texture is formed at the surface of the superstrate 10.

The method 800 allows formation of periodic or quasi-periodic structures with a controlled and precise distance at sub-micron level between consecutive patterns on the superstrate 10, thereby allowing maximization of light-trapping efficiency of the thin-film photovoltaic device.

Subsequently, at step 808, a TCO layer, for example the TCO layer 11 is deposited with conventional known methods on top of the surface of the superstrate having the micro-texture. The TCO layer 11 deposited also includes a micro-texture on a side that is distant from the surface of the superstrate having the micro-texture. The micro-texture on the TCO layer is formed either during deposition process (such as APCVD, LPCVD) or by wet-etching of the TCO layer 11. Further, the micro-texture formed on the TCO layer 11 are also of periodic or quasi-periodic in nature.

Thereafter, one or more semiconductor layers, for example the semiconductor layers 12-14, back contact layer, for example the back contact layer 15 and a cover substrate, for example the cover substrate 18 are deposited using conventional methods at steps 812, 814 and 816 respectively.

Following which the method 800 is terminated at step 818.

Various embodiments, as described above, provide a thin film photovoltaic device and a method to manufacture the thin film photovoltaic device, which have several advantages. One of the several advantages of the method is that it allows producing a well-defined periodic micro-texture onto substrates or superstrates of the thin-film photovoltaic devices in comparison to random micro-texture available in the prior art. Use of such structured micro-texture allows maximizing light-trapping efficiency of the thin-film photovoltaic devices. Further, unlike the prior art micro-texture parameters according to the present invention can be changed more easily as they are not dependent on the type of materials used. Further, given the production processes it is also possible to independently optimize the micro-texture parameters for maximum light-trapping.

While the invention has been disclosed in connection with the preferred embodiments shown and described in detail, various modifications and improvements thereon will become readily apparent to those ordinarily skilled in the art. Accordingly, the spirit and scope of the present invention is not to be limited by the foregoing examples, but is to be understood in the broadest sense allowable by law.

All documents referenced herein are hereby incorporated by reference.

1. Method for producing a light trapping layer on a transparent substrate for use in a photovoltaic device comprising at least the steps of:
i) providing a transparent substrate having a first substantially flat surface;
ii) applying a light trapping texture in the exposed surface of the transparent substrate, wherein the method is characterized in that step ii) comprises the steps of:
ii-1) providing a replication substrate having a replication texture exhibiting a negative image of the light trapping texture to be applied on said exposed surface of the transparent substrate;
ii-2) replicating said negative replication texture in the exposed surface of the transparent substrate.

2. Method according claim 1, characterized in that said negative replication texture is obtained by:
a) locally illuminating a photo-resist layer present on a master support;
b) developing said locally illuminated photo-resist layer thereby obtaining a master texture in the remaining photo-resist layer;
c) depositing one or more metal layers on said remaining photo-resist layer and said master support;
d) removing said stack of one or more metal layers from said master support.

3. Method according claim 2, characterized in that for obtaining said master texture in the remaining photo-resist layer, said photo-resist layer is illuminated using a focused sub-micron sized laser beam.

4. Method according claim 2 or 3, characterized in that step c) comprises the steps of
c1) sputtering a first metal layer on said remaining photo-resist layer; and
c2) growing by means of electro-plating a second metal layer on said first metal layer.

5. Method according claim 4, characterized in that said first and second metal layer contain a Ni-alloy or an Ag-alloy.

6. Method according any one of the claims 2-5, characterized in that step c) results in a stack of one or more metal layers having a texture exhibiting a negative image of the light trapping texture to be applied.

7. Method according any one of the claims 2-5, characterized in that step c) results in a stack of one or more metal layers having a texture exhibiting a positive image of the light trapping texture to be applied.

8. Method according claim 7, characterized in the further step of e) forming a replication substrate having a replication texture exhibiting a negative image of the light trapping texture to be applied on said stack of one or more metal layers having a texture exhibiting a positive image of the light trapping texture to be applied.

9. Method according any one of the claims 1-8, characterized in that steps ii-1) and ii-2) are preceded by the step of
ii-3) providing a layer of a viscous curable material on said first substantially flat surface of said transparent substrate and wherein step ii-2) comprises the step of
ii-4) curing said textured layer of a viscous curable material by means of light and/or heat.

10. Method according claim 9, characterized in that said layer of a viscous curable material is an ultra-violet curable material, such as a photo-polymer lacquer or a sol-gel material.

11. Method according any one of the claims 1-8, characterized in that steps ii-1) and ii-2) are preceded by the step of
ii-5) heating said first substantially flat surface of said transparent substrate above its deformation temperature and wherein step ii-2) comprises the step of
ii-6) cooling said heated textured first substantially flat surface of said transparent substrate below its deformation temperature.

12. Method according any one of the claims 1-8, characterized in that step ii-2) comprises the step of
ii-7) replicating said negative replication texture in the exposed surface of the transparent substrate by means of injection molding.

13. Method for producing a photovoltaic device comprising at least the steps of:
i) providing a transparent substrate having a first substantially flat surface;
ii) applying a light trapping texture in the exposed surface of the transparent substrate;
iii) depositing one or more semiconductor layers for photoelectric conversion on said light trapping texture;
iv) providing a cover substrate on said one or more semiconductor layers, wherein step ii) is performed according to any one or more of the claims 1-12.

14. Photovoltaic device for the photoelectric conversion of incident solar light comprising a stack of at least:
a transparent substrate having a first substantially flat surface;
a textured light trapping layer on said first surface;
one or more semiconductor layers for photoelectric conversion deposited on said textured light trapping layer; and
a cover substrate, characterized in stat the texture present in the light trapping layer is applied using the replication method according to any one or more of the claims 1-13.
